(19) United States
(12) Patent Application Publication
(10) Pub. No.: US 2023/0133029 A1
(43) Pub. Date: May 4, 2023

(54) LEADFRAME WITH PRE-SEPARATED LEADS

(71) Applicant: Texas Instruments Incorporated, Dallas, TX (US)

(72) Inventor: Makoto Shibuya, Beppu City (JP)

(73) Assignee: Texas Instruments Incorporated, (omitted)

(21) Appl. No.: 17/513,268

(22) Filed: Oct. 28, 2021

(51) Int. Cl. H01L 23/495; H01L 23/00; H01L 21/56; H01L 21/48

(52) U.S. Cl. CPC H01L 23/49555; H01L 21/561; H01L 21/4821; H01L 23/49582; H01L 24/97; H01L 23/4951; H01L 23/49513; H01L 24/16; H01L 24/32; H01L 24/73; H01L 2224/16245; H01L 2224/32245; H01L 2224/73265

(57) ABSTRACT

A semiconductor package includes a leadframe including a plurality of pre-separated leads on at least opposing sides. There is metal plating on a distal end of the plurality of pre-separated leads including on an outer facing edge. A semiconductor die having bond pads is mounted on the leadframe having the bond pads electrically connected to the plurality of pre-separated leads.

### FIELD

This Disclosure relates to leadframes for semiconductor packages.

### BACKGROUND

Leadframe-based semiconductor packages are well-known and widely used in the electronics industry to house, mount, and interconnect a variety of types of ICs. A conventional leadframe is typically die-stamped from a sheet of flat-stock metal, and includes a plurality of metal leads temporarily held together in a planar arrangement about a central region during semiconductor package manufacture by a rectangular frame comprising a plurality of expendable “dam-bars.” A mounting pad (or die pad) for a semiconductor die is supported in the central region by “tie-bars” that attach to the frame. The leads extend from a first end integral with the frame to an opposite second end adjacent to, but spaced apart from, the die pad. In a leadframe sheet (also sometimes referred to as a leadframe strip or a leadframe panel) having a plurality of joined leadframe units, where the leads between adjacent leadframe units are physically connected.

There is a constant search to lower the cost of semiconductor packages, especially for a small outline transistor (SOT) package, or a small outline package (SOP), which are each commonly used semiconductor packages, each being examples of the highest unit density leadframe sheet design for semiconductor packages, thus being the lowest cost. One known way to increase leadframe unit density on a leadframe sheet is by reducing the leadframe unit pitch through using an interdigitated lead design. Another known way to increase the leadframe unit density is to have a mold cavity design that features dam bars that run an entire dimension, such as the length, of the leadframe sheet. This high unit density leadframe sheet design enables the mold injection using appropriately configured mold plates to simultaneously cover (mold) an entire vertical row of the leadframe sheet, where the molding process is sped up because the mold injection is implemented simultaneously on one row comprising a plurality of units, instead of conventionally molding a single unit at a time.

### SUMMARY

This Summary is provided to introduce a brief selection of disclosed concepts in a simplified form that are further described below in the Detailed Description including the drawings provided. This Summary is not intended to limit the claimed subject matter’s scope.

Disclosed aspects include leadframe sheets having dam bars that run an entire dimension of the sheet and interdigitated leads between adjacent units, that both reduce the leadframe unit pitch and further provide pre-separated leads. The pre-separated leads further reduces the leadframe unit pitch for the leadframe sheet, thus further reducing unit cost. The unit pitch is reduced because with pre-separated leads the conventionally needed cut margin for the leadframe sheet is eliminated since there is no cutting of the leads needed.

### BRIEF DESCRIPTION OF THE DRAWINGS

Reference will now be made to the accompanying drawings, which are not necessarily drawn to scale, wherein:

FIG. 1A is a top view depiction showing 2 adjacent units of a molded leadframe sheet for SOT packages, where the molded leadframe sheet includes both i) dam bars that run an entire dimension shown in the up/down direction of the molded leadframe sheet, and ii) interdigitated leads between adjacent leadframe units. There are also shown some design parameters and what they represent for the leadframe sheet.

FIG. 1B is a top view depiction showing 2 adjacent units of a disclosed molded leadframe sheet for SOT packages that includes both the interdigitated leads now shown as being disclosed pre-separated leads and dam bars that run an entire dimension as shown in FIG. 1A, according to an example aspect.

FIGS. 2A and 2B show cross-sectional views of a wirebonded semiconductor package and a flipchip on lead (FCOL) semiconductor package, respectively, each having a semiconductor die having a top surface including bond pads and disclosed pre-separated leads. There is metal plating on the distal end of the pre-separated leads including plating on the distal end face of the leads due to the leads being pre-separated leads, so that the distal end face is exposed during the metal plating process for the plating of the pre-separated leads.

FIGS. 3A-3C are successive views relating to a disclosed method for processing a disclosed molded leadframe sheet having pre-separated leads for forming a disclosed wirebonded semiconductor package, according to an example aspect. In FIG. 3A a leadframe sheet is shown comprising a plurality of leadframe units connected together in a 2-dimensional array each including a die pad, pre-separated leads, and a dam bar that runs an entire length of the leadframe sheet.

FIG. 3B shows the leadframe sheet after mounting a semiconductor die top side up on the die pad that includes a die attach material thereon (not shown) for each of the leadframe units, and then wire bonding to add bond wires between the bond pads and an inner portion of the pre-separated leads.

FIG. 3C shows the in-process leadframe sheet comprising a plurality of semiconductor package resulting after molding to form a mold material for the respective semiconductor packages.

### DETAILED DESCRIPTION

Example aspects are described with reference to the drawings, wherein like reference numerals are used to designate similar or equivalent elements. Illustrated ordering of acts or events should not be considered as limiting, as some acts or events may occur in different order and/or concurrently with other acts or events. Furthermore, some illustrated acts or events may not be required to implement a methodology in accordance with this Disclosure.

Also, the terms “connected to” or “connected with” (and the like) as used herein without further qualification are intended to describe either an indirect or direct electrical connection. Thus, if a first device “connects” to a second device, that connection can be through a direct electrical connection where there are only parasitics in the pathway, or through an indirect electrical connection via intervening items including other devices and connections. For indirect connecting, the intervening item generally does not modify the information of a signal but may adjust its current level, voltage level, and/or power level.

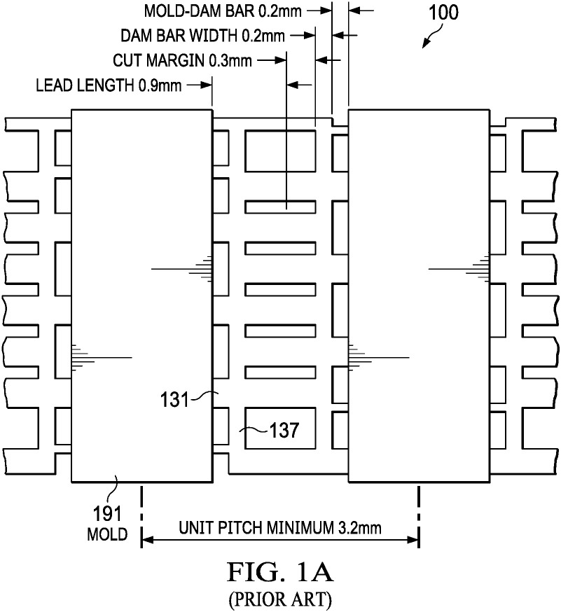

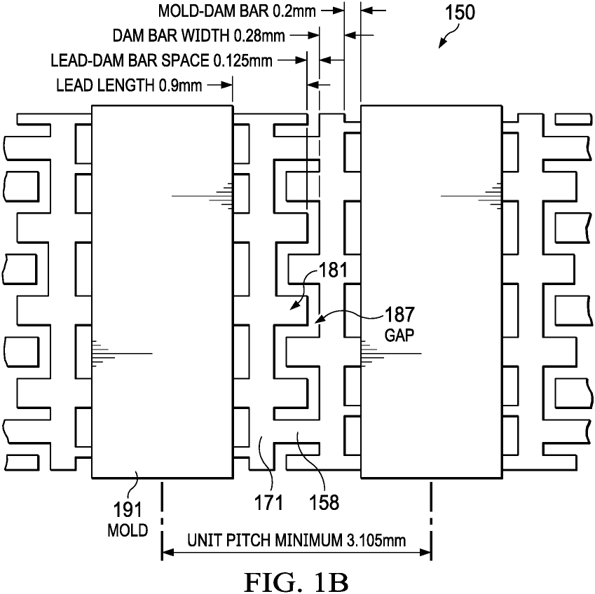

FIG. 1A is a top view depiction showing 2 adjacent units of a molded leadframe sheet 100 for SOT packages, where the mold is shown as 191. The molded leadframe sheet 100 includes both i) dam bars 137 that run an entire dimension shown in the up/down direction of the molded leadframe sheet 100, and ii) interdigitated leads 131 between adjacent leadframe units. There are also shown some design parameters and what they represent for the leadframe sheet, including the lead cut margin shown as being 0.3 mm. The minimum leadframe unit pitch for the molded leadframe sheet 100 for a mold 191 width of 1.6 mm is shown as being 3.2 mm.

FIG. 1B is a top view depiction showing 2 adjacent units of a disclosed molded leadframe sheet 150 for SOT packages that includes both the interdigitated leads shown as being disclosed pre-separated leads 181 and dam bars 171 that run an entire dimension as shown in FIG. 1B, according to an example aspect. The pre-separated leads 181 remove the required lead cut margin for the molded leadframe sheet 100 shown in FIG. 1A because the pre-separated leads 181 being already separated having a gap 187 in between do not need to be cut. The lead length for the pre-separated leads 181 has remained unchanged relative to the leads 131 for the molded leadframe sheet 100 shown in FIG. 1A being 0.9 mm.

Due to the removal of the need for the lead cut margin shown in FIG. 1A of 0.3 mm that is replaced by a smaller pre-separated lead 181 to dam bar 171 spacing of only 0.125 mm, a minimum spacing between adjacent ones of the pre-separated leads 181 represented by the gap 187 is less than or equal to a thickness of the leadframe (which is the same as the thickness of the pre-separated leads 181). The thickness of the leadframe may be 0.10 mm to 0.15 mm, and a minimum spacing between adjacent ones of the pre-separated lead 181 represented by the gap 187 can be 80% to 100% of the thickness of the leadframe. The minimum unit pitch for the disclosed molded leadframe sheet 150 having the same mold width of 1.6 mm as for the molded leadframe sheet 100 shown in FIG. 1A is 3.025 mm. The pre-separated leads 181 thus provide a significantly higher molded leadframe unit density as compared to the molded leadframe sheet 100 shown in FIG. 1A.

There is also shown what is termed dummy leads 158 that connect between dam bars 171 of adjacent units that can be optionally included for additional leadframe mechanical robustness. The dummy leads 158 are cut during the singulation of the molded sheet, and are dummy leads (as opposed to actual leads) because the dummy leads are not used as leads, wherein contrast the pre-separated leads 181 as with any lead are electrically coupled to the bond pads of the semiconductor die for the semiconductor package. The dam bar 171 may optionally be wider as compared to the dam bar 137 for the molded leadframe sheet 100 shown in FIG. 1A for making leadframe strip more mechanically robust to compensate for the pre-separated leads 181 being already separated from dam-bar. For example, the width of the dam bar 171 can be around 0.3 mm as compared to the dam bar 137 shown in FIG. 1A that may have a width of 0.2 mm.

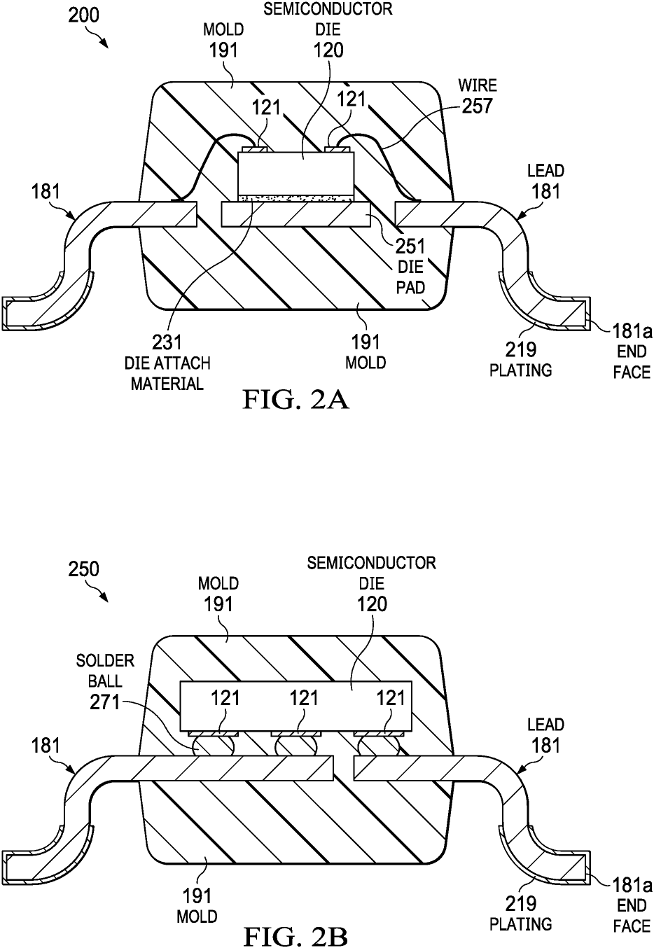

FIGS. 2A and 2B show cross-sectional views of a wirebonded semiconductor package 200 and a flipchip on lead (FCOL) semiconductor package 250, respectively, each having a semiconductor die 120 having a top surface including bond pads 121 and disclosed pre-separated leads 181. There is metal plating 219 on the distal end of the pre-separated leads 181 including plating 219 on the distal end face 181a of the leads 181 due to the leads 181 being pre-separated leads, so that the distal end face 181a is exposed during the metal plating process for plating the pre-separated leads 181.

The wirebonded semiconductor package 200 includes a die pad 251 provided by the leadframe, where a bottom side of the semiconductor die 120 is attached to the die pad 251 by a die attach material 231. The mold material is again shown as 191. There are also bond wires 257 between the bond pads 121 and an inner portion (within the mold material 191) of the pre-separated leads 181. The FCOL semiconductor package 250 includes solder balls 221 that provide an electrical connection between the bond pads 121 and the inner portion of the pre-separated leads 181.

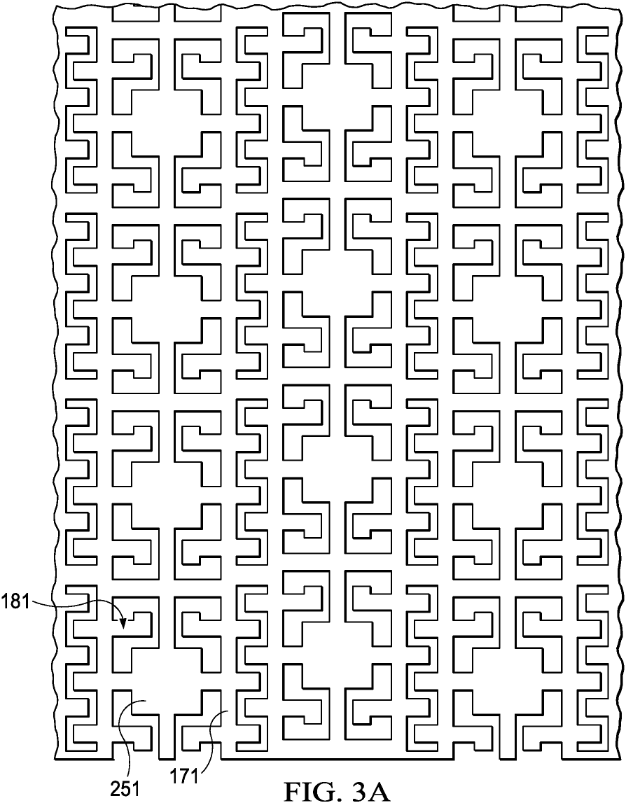

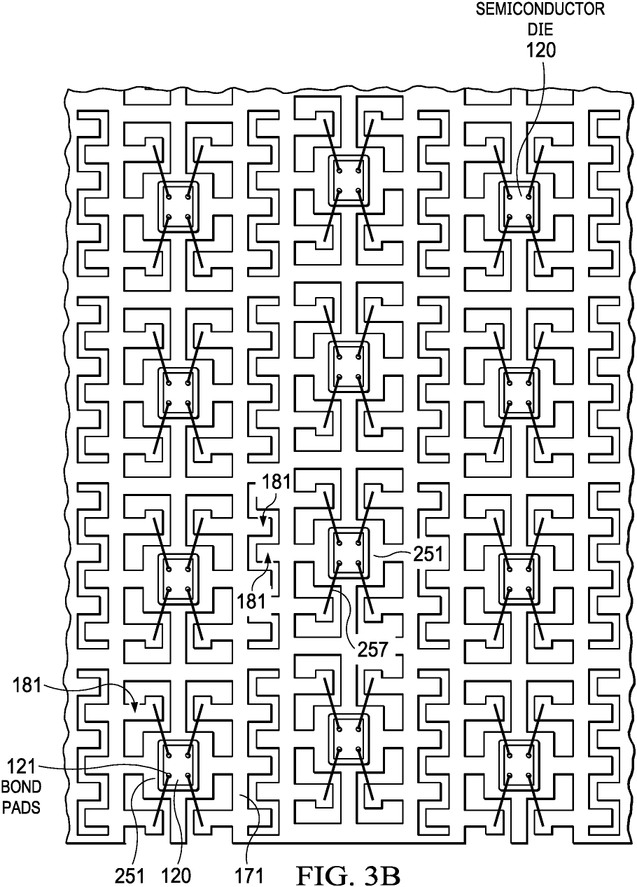

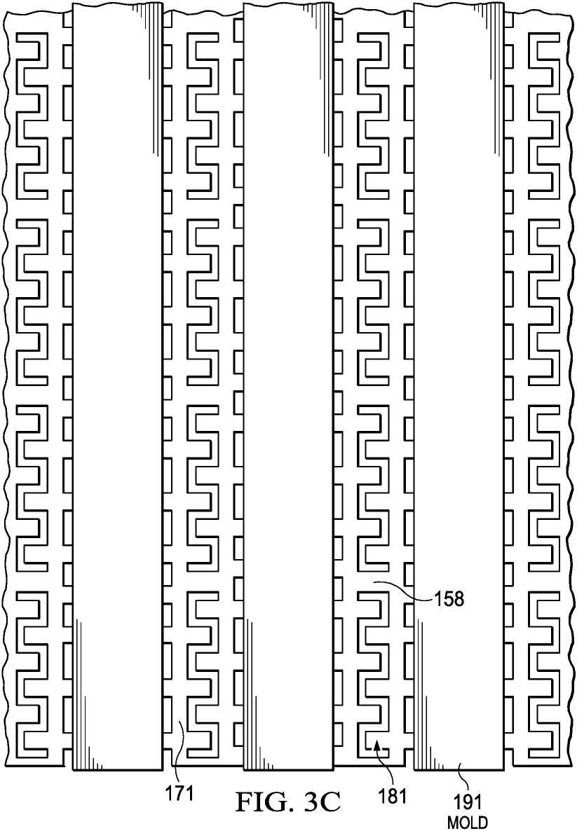

FIGS. 3A-3C are successive views relating to a disclosed method for processing a disclosed molded leadframe sheet having pre-separated leads 181 for forming a disclosed wirebonded semiconductor package, according to an example aspect. In FIG. 3A a leadframe sheet is shown comprising a plurality of leadframe units connected together in a 2-dimensional array each including a die pad 251, pre-separated leads 181, and a dam bar 171 that runs an entire length of the leadframe sheet. As described above the dam bar 171 enables mold injection using appropriately configured mold plates to cover during a single injection an entire vertical row of the leadframe sheet, where mold injection is implemented one row at a time. The pre-separated leads 181 can be seen to be configured to be interdigitated relative to adjacent units in the width direction of the leadframe sheet.

FIG. 3B shows the leadframe sheet after mounting a semiconductor die 120 top side up on the die pad 251 that includes a die attach material thereon (not shown) for each of the leadframe units, and then wire bonding to add bond wires 257 between the bond pads 121 on the semiconductor die 120 and an inner portion of the pre-separated leads 181. In the flipchip arrangement (shown in FIG. 2B described above), one would simply replace the die pad 251 and bond wires 257 shown in FIG. 3B by a flipchip attach process using solder balls for the electrical connection.

FIG. 3C shows the in-process leadframe sheet comprising a plurality of semiconductor package resulting after molding to form a mold material 191 for the respective semiconductor packages. Because the dam bars 171 run an entire dimension of the leadframe sheet, this enables the mold injection using appropriately configured mold plates to cover an entire vertical row of the leadframe sheet during a single injection, where mold injection is one row at a time. Subsequent assembly processing can comprise a trim/form process, while some semiconductor packages may use trim and singulation. For example, package unit singulation can be used which includes cutting the mold material 191 and the optional dummy leads 158, but not the pre-separated leads 181 as they are pre-separated.

Disclosed aspects leave a traceable mark on a final semiconductor package because the pre-separated leads 181 result in a unique feature reflected in the pattern of the plating 219 including the ends of the pre-separated leads 181 including the sidewalls and also on the distal end faces 181a (shown in FIGS. 2A and 2B described above) which is similar to wettable flank leads. In contrast, for a conventional lead design this sidewall plating on the distal ends/edges the leads is not possible because the metal plating step always comes before separating the leads between adjacent leadframe units.

Disclosed aspects can be integrated into a variety of assembly flows to form a variety of different semiconductor packages and related products. The semiconductor package can comprise single IC die or multiple IC die, such as configurations comprising a plurality of stacked IC die, or laterally positioned IC die. A variety of package substrates may be used. The IC die may include various elements therein and/or layers thereon, including barrier layers, dielectric layers, device structures, active elements and passive elements including source regions, drain regions, bit lines, bases, emitters, collectors, conductive lines, conductive vias, etc. Moreover, the IC die can be formed from a variety of processes including bipolar, insulated-gate bipolar transistor (IGBT), CMOS, BiCMOS and MEMS.

Those skilled in the art to which this Disclosure relates will appreciate that many variations of disclosed aspects are possible within the scope of the claimed invention, and further additions, deletions, substitutions, and modifications may be made to the above-described aspects without departing from the scope of this Disclosure.

1. A leadframe for a semiconductor package, comprising:
a plurality of pre-separated leads on at least opposing sides, and
metal plating on a distal end of the plurality of pre-separated leads including on an outer facing edge.

2. The leadframe of claim 1, wherein the metal plating comprises tin or NiPdAu, having a thickness in a range of 3 µm to 20 µm.

3. The leadframe of claim 1, wherein a minimum spacing between adjacent ones of the pre-separated leads is less than or equal to a thickness of the leadframe.

4. A leadframe sheet, comprising:
a plurality of leadframe units each including a plurality of pre-separated leads and dam bars on at least opposing sides, connected together in a 2-dimensional array so that adjacent ones of the plurality of leadframe units have the plurality of pre-separated leads interdigitated, wherein the plurality of pre-separated leads are physically separate and have an outer edge, and
wherein the dam bars that run an entire dimension of the leadframe sheet for enabling mold injection using mold plates to cover during a single injection an entire vertical row of the leadframe sheet.

5. The leadframe sheet of claim 4, further comprising metal plating on a distal end of the plurality of pre-separated leads including on the outer facing edges.

6. The leadframe sheet of claim 4, further comprising at least one dummy lead connection between the dam bars of adjacent ones of the plurality of leadframe units.

7. The leadframe sheet of claim 5, wherein the metal plating comprises tin or NiPdAu, having a thickness in a range of 3 µm to 20 µm.

8. The leadframe sheet of claim 4, wherein a spacing between the pre-separated leads and the dam bars is 0.10 mm to 0.18 mm.

9. A method of assembling a semiconductor package, comprising:
providing a leadframe sheet, comprising:
a plurality of leadframe units each including a plurality of pre-separated leads and dam bars on at least opposing sides, connected together in a 2-dimensional array, wherein adjacent ones of the plurality of pre-separated leads are physically separated each having an outer facing edge, and
wherein the dam bars that run an entire dimension of the leadframe sheet for enabling mold injection using appropriately configured mold plates to cover during a single injection an entire vertical row of the leadframe sheet;
mounting a semiconductor die on each of the leadframe units;
molding to form a mold compound to provide a molded leadframe sheet by simultaneously molding one of the vertical rows at a time, and repeating the molding to provide the mold compound for each of the vertical rows;
metal plating on a distal and of the plurality of pre-separated leads including on the outer facing edge, and
separating the molded leadframe sheet into a plurality of the semiconductor packages.

10. The method of claim 9, wherein the mounting of the semiconductor die is with a top side of the semiconductor die facing up.

11. The method of claim 9, wherein the mounting of the semiconductor die is with a flip chip configuration with a bottom side of the semiconductor die facing down.

12. The method of claim 9, wherein the metal plating comprises tin or NiPdAu, having a thickness in a range of 3 µm to 20 µm.

13. The method of claim 9, wherein the plurality of leads comprise gull-wing leads.

14. The method of claim 9, wherein a spacing on the leadframe sheet between the pre-separated leads and the dam bars is 0.10 mm to 0.18 mm.

15. A semiconductor package, comprising:
a leadframe, comprising:
a plurality of pre-separated leads on at least opposing sides, and
metal plating on a distal end of the plurality of pre-separated leads including on an outer facing edge, and
a semiconductor die having bond pads mounted on the leadframe having the bond pads electrically connected to the plurality of pre-separated leads.

16. The semiconductor package of claim 15, wherein the semiconductor package comprises a flipchip package.

17. The semiconductor package of claim 15, wherein the semiconductor die comprises an integrated circuit (IC).

18. The semiconductor package of claim 15, wherein the metal plating comprises tin or NiPdAu, having a thickness in a range of 3 µm to 20 µm.

19. The semiconductor package of claim 15, wherein a minimum spacing between adjacent ones the pre-separated leads is less than or equal to a thickness of the leadframe.

20. The semiconductor package of claim 15, wherein the plurality of leads comprise gull-wing leads.
